(19) United States
(12) Patent Application Publication
(10) Pub. No.: US 2013/0234991 A1
(43) Pub. Date: Sep. 12, 2013

(54) OPTIMIZED HEMI-ELLIPSOIDAL LED SHELL

(71) Applicant: NEONODE INC., SANTA CLARA, CA (US)

(72) Inventor: LARS SPARF, VALLINGBY (SE)

(21) Appl. No.: 13/862,392

(22) Filed: Apr. 13, 2013

Related U.S. Application Data
(63) Continuation-in-part of application No. 13/424,472, filed on Mar. 20, 2012.
Application No. 13/424,472 is a continuation-in-part of application No. PCT/US11/29191, filed on Mar. 21, 2011.
(60) Provisional application No. 61/564,124, filed on Nov. 28, 2011.
(60) Provisional application No. 61/410,930, filed on Nov. 7, 2010.

(51) Int. Cl. G06F 3/042; H01L 31/0232; H01L 33/58

(52) U.S. Cl. CPC G06F 3/042; H01L 33/58; H01L 31/0232
USPC 345/175; 257/98; 257/432

(57) ABSTRACT

A hemi-ellipsoidal light module that includes a substrate for placement on a printed circuit board, a light element mounted on the substrate, and a molded plastic shell encasing the light element and having a geometry of a partial semi-ellipse rotated through a semi-circle about an axis on the light element.

This application is a continuation-in-part of U.S. application Ser. No. 13/424,472, entitled OPTICAL TOUCH SCREEN WITH TRI-DIRECTIONAL MICRO-LENSES, filed on Mar. 20, 2012 by inventors Lars Sparf, Stefan Holmgren, Magnus Goertz, Thomas Eriksson, Joseph Shain, Anders Jansson, Niklas Kvist, Robert Pettersson and John Karlsson.

U.S. application Ser. No. 13/424,472 is a non-provisional of U.S. Provisional Application No. 61/564,124, entitled OPTICAL TOUCH SCREEN WITH TRI-DIRECTIONAL MICRO-LENSES, filed on Nov. 28, 2011 by inventors Lars Sparf, Stefan Holmgren, Magnus Goertz, Thomas Eriksson, Joseph Shain, Anders Jansson, Niklas Kvist, Robert Pettersson and John Karlsson. U.S. application Ser. No. 13/424,472 is also a continuation-in-part of PCT Application No. PCT/US11/29191, entitled LENS ARRANGEMENT FOR LIGHT-BASED TOUCH SCREEN, filed on Mar. 21, 2011 by inventors Magnus Goertz, Thomas Eriksson, Joseph Shain, Anders Jansson, Niklas Kvist, Robert Pettersson, Lars Sparf and John Karlsson.

PCT/US11/29191 is a non-provisional of U.S. Provisional Application No. 61/410,930, entitled OPTICAL TOUCH SCREEN SYSTEMS USING REFLECTED LIGHT, filed on Nov. 7, 2010 by inventors Magnus Goertz, Thomas Eriksson, Joseph Shain, Anders Jansson, Niklas Kvist, Robert Pettersson and Lars Sparf.

### FIELD OF THE INVENTION

The present invention relates to molded plastic shells for light emitters and light detectors.

### BACKGROUND OF THE INVENTION

Conventional light-emitting diodes (LEDs) include a semiconductor light source mounted on a substrate inside a molded plastic shell, which acts as a refractive intermediary between the relatively high index semiconductor and the low index open air. As such, the plastic shell distributes light from the semiconductor and forms the angular distribution of the light emission by acting as a lens.

In conventional LEDs, the plastic shells are cylindrical or hemispherical, providing similar light intensity distributions in both vertical and horizontal dimensions.

### SUMMARY OF THE DESCRIPTION

Aspects of the present invention relate to novel shell design for light emitters, optimized to provide more radiant intensity in the forward direction than conventional cylindrical or hemispherical lenses. The novel shell design concentrates light distribution in the vertical dimension.

There is thus provided in accordance with an embodiment of the present invention a hemi-ellipsoidal light module that includes a substrate for placement on a printed circuit board, a light element mounted on the substrate, and a molded plastic shell encasing the light element and having a geometry of a partial semi-ellipse rotated through a semi-circle about an axis on the light element.

### BRIEF DESCRIPTION OF THE DRAWINGS

The present invention will be more fully understood and appreciated from the following detailed description, taken in conjunction with the drawings in which:

FIG. 1 is an illustration of a prior art light-based touch screen;

FIG. 2 is a simplified perspective view of a light emitter module mounted on a printed circuit board, in accordance with an embodiment of the present invention;

FIG. 3 is an illustration of distribution of light emitted by a light emitter module in a plane parallel to a screen surface, in accordance with an embodiment of the present invention;

FIG. 4 is an illustration of distribution of light emitted by a light emitter module in a plane parallel to a screen surface, in accordance with an embodiment of the present invention;

FIG. 5 is a simplified diagram of angular light intensity distributions for light emitted by a prior art light emitter module;

FIG. 6 is a simplified diagram of angular light intensity distributions for light emitted by a light emitter module in accordance with an embodiment of the present invention;

FIG. 7 is a simplified perspective view of a hemi-ellipsoidal plastic shell for a light emitter module, in accordance with an embodiment of the present invention;

FIG. 8 is a simplified diagram of a side view of a light emitter encased in the plastic shell of FIG. 7; and

FIG. 9 is a simplified diagram of a top view of a light emitter encased in the plastic shell of FIG. 7.

### DETAILED DESCRIPTION

Aspects of the present invention relate to a novel shell design for light-emitting diodes (LEDs). LEDs having the novel shell design are of advantage for use with many different applications. One such advantage relates to their use with light-based touch screens.

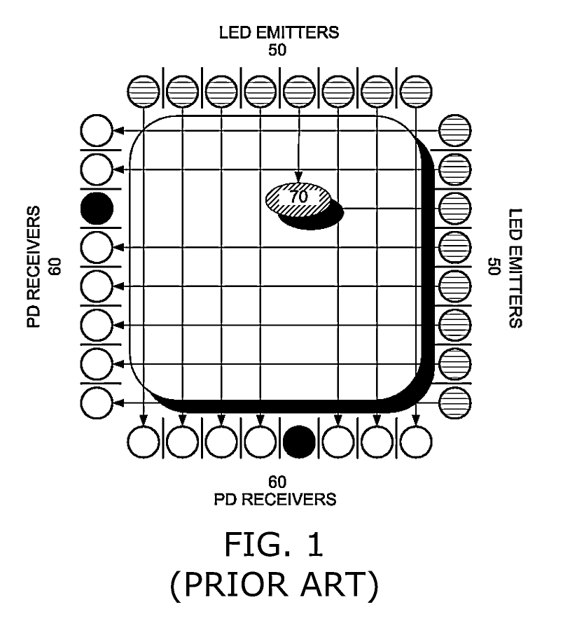

Conventional light-based touch screens operate by emitting light beams across a touch screen from two adjacent edges, and detecting whether the light beams are blocked from reaching detectors at the two opposite edges. In this regard, reference is made to FIG. 1, which is an illustration of a prior art light-based touch screen. FIG. 1 shows LEDs 50, which emit invisible infrared light, aligned along two adjacent edges of a display. Across from LEDs 50 are corresponding photodiode (PD) light receivers 60, which receive the light emitted by LEDs 50. However, when an object 70 touches the display, it blocks light emitted by one or more specific LEDs 50 from reaching their corresponding PDs 60. As such, object 70 is detected when light is not detected by the corresponding PDs 60. Since the PDs are arranged along two dimensions of the display, the blocked PDs on each edge suffice to determine the spatial location of object 70 on the display.

In some embodiments of the present invention, wide light beams cover the entire screen, and this enables very precise touch coordinate calculation. These embodiments are described in detail in applicant's co-pending application Ser. No. 13/424,472, entitled OPTICAL TOUCH SCREEN WITH TRI-DIRECTIONAL MICRO-LENSES, the contents of which are hereby incorporated by reference in their entirety.

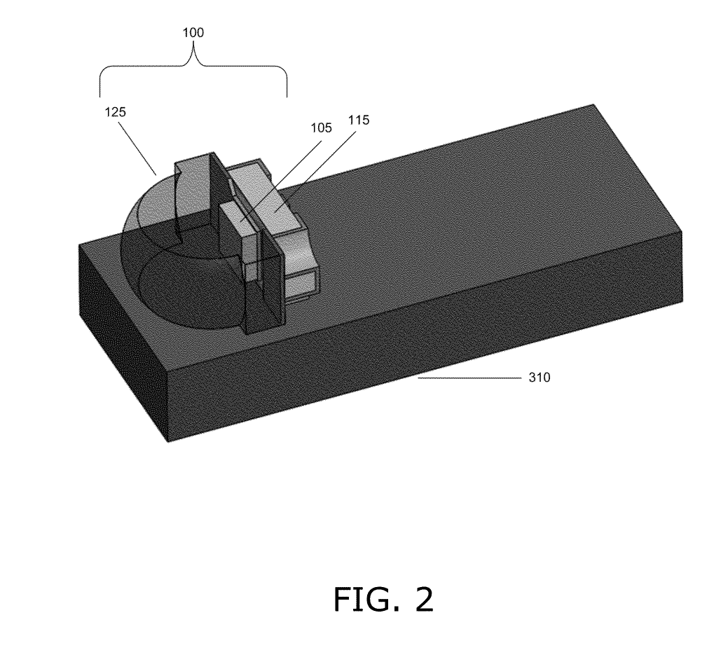

Reference is made to FIG. 2, which is a simplified perspective view of a light emitter module 100 mounted on a printed circuit board (PCB) 310, in accordance with an embodiment of the present invention.

Light emitter module 100 includes a light emitting semiconductor 105 mounted on a substrate 115 and encased in a molded plastic shell 125.

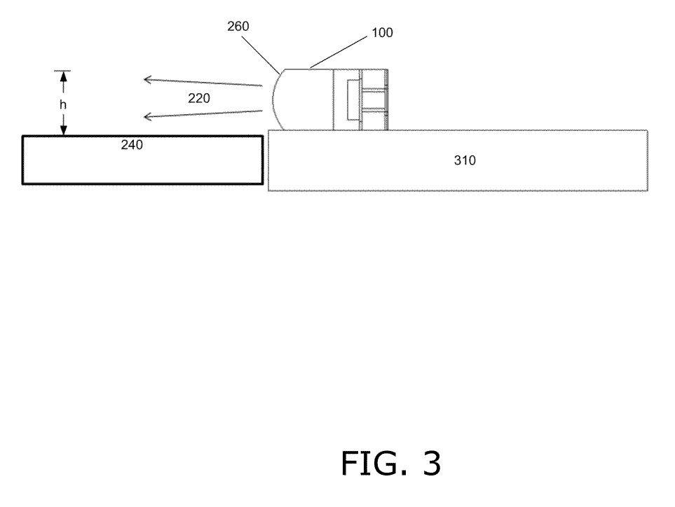

Reference is made to FIG. 3, which is an illustration of distribution of light emitted by light emitter module 100 in a plane parallel to a screen surface 240, in accordance with an embodiment of the present invention. FIG. 3 shows a side view of light emitter module 100, encased in a molded plastic shell 260 and mounted on PCB 310. An angular spread, denoted by h, is narrow, directing light beams 220 substantially parallel to screen surface 240.

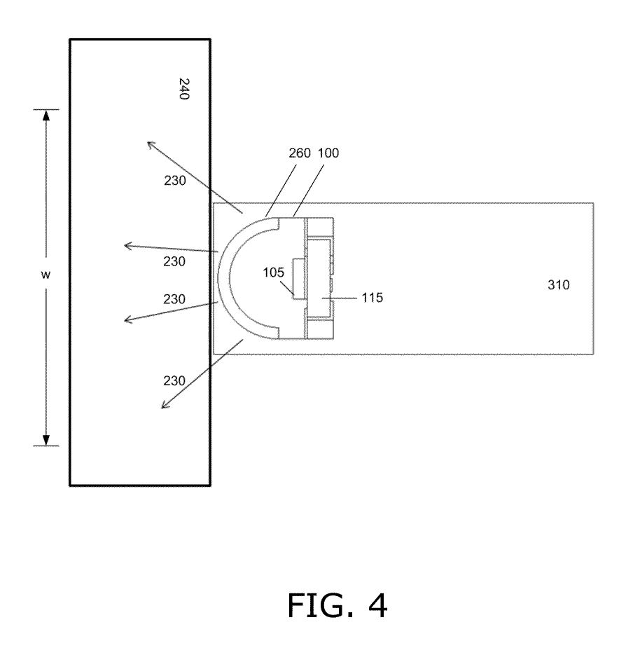

Reference is made to FIG. 4, which is an illustration of distribution of light emitted by light emitter module 100 in a plane parallel to screen surface 240, in accordance with an embodiment of the present invention. FIG. 4 shows a top view of light emitter module 100 mounted on PCB 310; i.e., the view in FIG. 4 is looking down onto screen surface 240. The angular emission, denoted w, is wide, and spreads light beams 230 across a wide angle to cover a large area of screen surface 240. Light emitter module 100 includes a semiconductor light source 105, a substrate 115, and molded plastic shell 260.

Together, FIGS. 3 and 4 show that embodiments of the present invention generate a narrow angular emission in the height dimension of an emitter (FIG. 3); i.e., perpendicular to the screen surface, and maintain a wide lateral angular emission, parallel to the screen surface (FIG. 4).

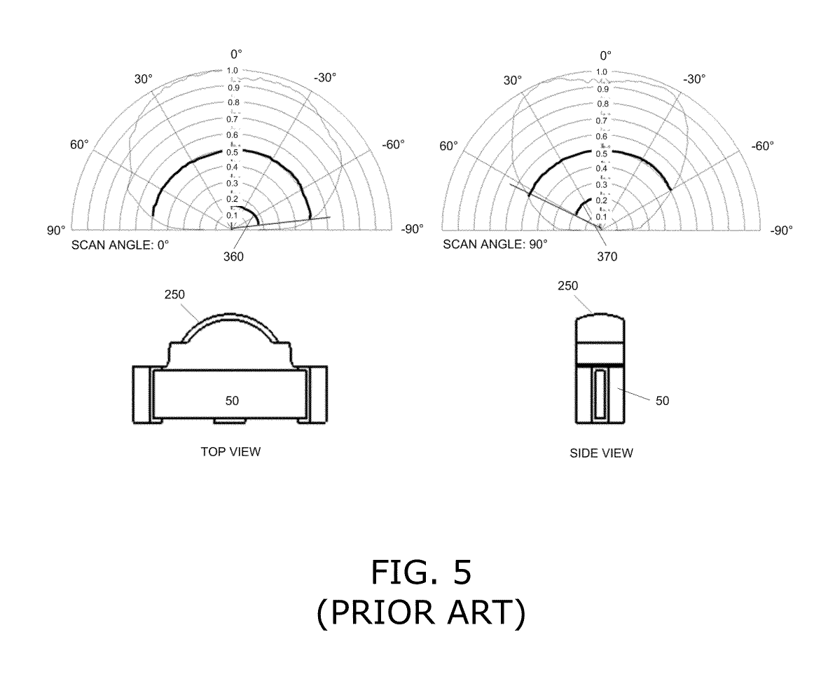

Reference is made to FIG. 5, which is a simplified diagram of angular light intensity distributions for light emitted by a prior art light emitter module 50. FIG. 5 shows light emission for an emitter having a hemispherical plastic shell 250. FIG. 5 shows top and side views of light emitter module 50 with hemispherical plastic shell 250. Above each emitter view is a normalized intensity graph showing relative radiant intensity vs. angular displacement. The outermost semi-circle represents a maximum light intensity detected by a light detector at any point across a 180° arc surrounding the light source. The maximum intensity is normalized to 1.0. The inner semicircles represent lower relative light intensities; e.g., 80%, 60%, of the maximum. A half-intensity angle, θ_{1/2}, is used to characterize how far in degrees from the on-axis perspective a particular LED's luminous intensity drops to 50%. On the left side of FIG. 5 the top view of light emitter module 50 shows that light is distributed across a wide arc covering a large area of the screen, characterized by a large half-intensity angle 360. Similarly, on the right side of FIG. 5 the side view of emitter 50 shows that light is distributed across a wide range of heights above the screen surface, characterized by a large half-intensity angle 370. The minor difference between distributions across vertical and horizontal axes is due to the shell being wider than it is high.

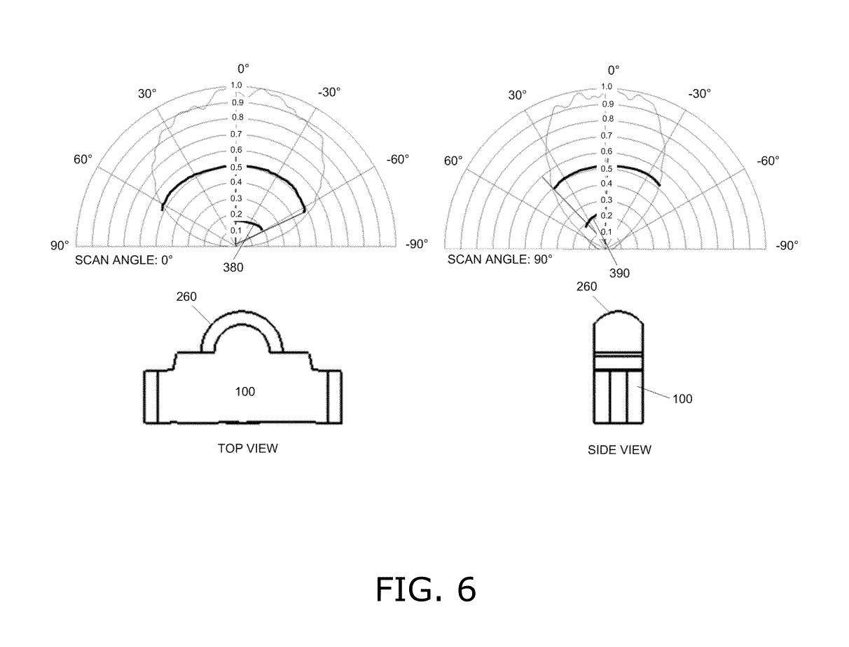

Reference is made to FIG. 6, which is a simplified diagram of angular light intensity distributions for light emitted by a light emitter module 100 in accordance with an embodiment of the present invention. FIG. 6 shows light emission for an emitter having a plastic shell according to the present invention. FIG. 6 shows top and side views of light emitter module 100 encased in plastic shell 260 formed as a partial semi-ellipse rotated through a semi-circle. Above each emitter view is a normalized intensity graph showing relative radiant intensity vs. angular displacement. On the left side of FIG. 6 the intensity graph above the top view of emitter 100 shows that light is distributed across a wide angle and therefore covers a wide wedge of the screen characterized by a large half-intensity angle, θ_{1/2}, 380, similar to that of hemispherical plastic shell 250 of FIG. 5. This is because the lateral cross-section of plastic shell 260 is a semi-circle. However, the intensity graph above the side view of light emitter module 100 on the right side of FIG. 6 shows that light is distributed within a substantially narrower range of heights than the emitter of FIG. 5, characterized by a small half-intensity angle 390. This focused intensity is a result of plastic shell 260 being formed as a partial semi-ellipse along the height of light emitter module 100; i.e., along the dimension perpendicular to the screen surface. By narrowing the total radiation within a narrow range of angular displacements, the absolute radiant intensity is greater than that in FIG. 5.

Together, FIGS. 5 and 6 illustrate the difference in light distribution between a prior art emitter with a hemispherical plastic shell, and an emitter according to the teachings of the present invention whose plastic shell is formed as a partial semi-ellipse rotated through a semi-circle.

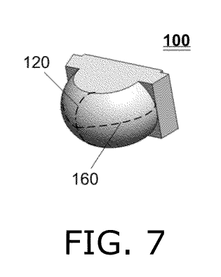

Reference is made to FIG. 7, which is a simplified perspective view of a hemi-ellipsoidal plastic shell for a light emitter module 100, in accordance with an embodiment of the present invention. As shown in FIG. 7, the longitudinal cross-section of the plastic shell is a partial semi-ellipse 120, and the lateral cross-section of the plastic shell is a semi-circle 160. When LEDs 100 of FIG. 7 are used in optical touch screens as shown in FIG. 1, and as described in applicant's co-pending application Ser. No. 13/424,472, entitled OPTICAL TOUCH SCREEN WITH TRI-DIRECTIONAL MICRO-LENSES, they optimize use of available light for touch detection vis-à-vis conventional LEDs having cylindrical or hemispherical plastic shells.

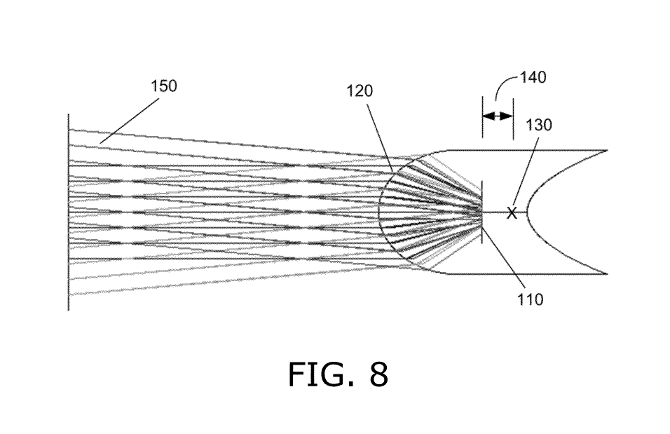

Reference is made to FIG. 8, which is a simplified diagram of a side view of a light emitter that incorporates the shell of FIG. 7. As shown in FIG. 8, a light emitting semiconductor surface 110 is encased in a shell having a partial semi-elliptical cross-section 120 with a focal point 130 located at a distance 140 behind semiconductor surface 110. This shell projects the light emitted from the semiconductor surface into an essentially collimated vertical field 150, corresponding to the right-hand graph in FIG. 6.

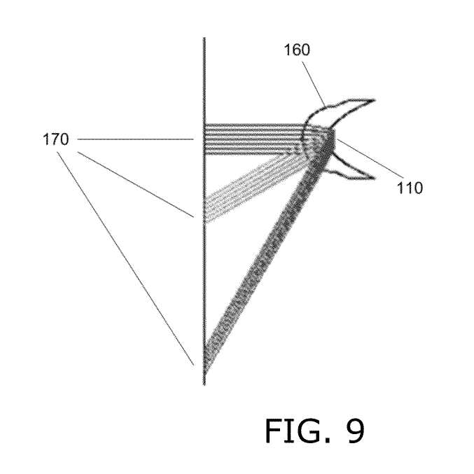

Reference is made to FIG. 9, which is a simplified diagram of a top view of a light emitter that incorporates the shell of FIG. 7. As shown in FIG. 9, the shell has a semi-circular cross-section 160 and evenly distributes the emitted light over a wide angular range 170, corresponding to the left-hand graph in FIG. 6. FIG. 9 shows how all points on the semiconductor surface 110 contribute light to a wide angular range.

Together, FIGS. 8 and 9 show that the shell has a three-dimensional geometry of partial semi-ellipse 120 rotated through semi-circle 160 about an axis on light emitting semiconductor surface 110.

Although the above discussion relates to LED modules, it will be appreciated by those skilled in the art that the shell of FIG. 7 may also be used with photodiode detectors.

In the foregoing specification, the invention has been described with reference to specific exemplary embodiments thereof. It will, however, be evident that various modifications and changes may be made to the specific exemplary embodiments without departing from the broader spirit and scope of the invention as set forth in the appended claims. Accordingly, the specification and drawings are to be regarded in an illustrative rather than a restrictive sense.

What is claimed is:

1. A hemi-ellipsoidal light module, comprising:
a substrate for placement on a printed circuit board;
a light element mounted on said substrate; and
a molded plastic shell encasing said light element and having a geometry of a partial semi-ellipse rotated through a semi-circle about an axis on said light element.

2. The light module of claim 1 wherein the partial semi-ellipse is sized and shaped to position its focus at a designated distance behind said light element.

3. The light module of claim 1 wherein said light element is a light-emitting diode (LED).

4. The light module of claim 1 wherein said light element is a photodiode (PD) receiver.

5. An optical touch screen, comprising:
a housing;
a display mounted in said housing;
a plurality of light emitters mounted in said housing for transmitting light pulses across said display, each said emitter comprising a light emitting semiconductor encased in a molded plastic shell that comprises a geometry of a partial semi-ellipse rotated through a semi-circle about an axis on said light emitting semiconductor;
a plurality of light receivers mounted in said housing, for receiving the transmitted light pulses, each said receiver comprising a light detecting semiconductor encased in a molded plastic shell that comprises a geometry of a partial semi-ellipse rotated through a semi-circle about an axis on said light detecting semiconductor; and
a calculating unit, mounted in said housing and connected to said light receivers, for determining a location of a pointer on said display that partially blocks the light pulses emitted by said light emitters, based on outputs of said light receivers.
